(19) United States
(12) Patent Application Publication
(10) Pub. No.: US 2021/0159198 A1
(43) Pub. Date: May 27, 2021

(54) SEMICONDUCTOR STRUCTURE AND MANUFACTURING METHOD THEREOF

(71) Applicant: NANYA TECHNOLOGY CORPORATION, New Taipei City (TW)

(72) Inventor: Hsih-Yang CHIU, Taoyuan City (TW)

(21) Appl. No.: 16/693,354

(22) Filed: Nov. 24, 2019

(51) Int. Cl. H01L 23/00

(52) U.S. Cl. CPC H01L 24/13; H01L 2224/11622; H01L 2224/1301; H01L 24/11

(57) ABSTRACT

A semiconductor structure includes a dielectric layer, a conductive pad embedded in the dielectric layer, and a bump disposed on the conductive pad, wherein the bump has a first top width and a bottom width, the first top width is greater than the bottom width, and a pair of spacers is disposed adjacent to the bump.

### BACKGROUND

### Field of Invention

The present disclosure relates to a semiconductor structure and a manufacturing method thereof.

### Description of Related Art

In the production of various electronic elements, techniques for mounting electronic components such as semiconductor chips using solder bumps or producing semiconductor laminated packages are widely used. In order to miniaturize, lighten and improve electronic devices in accordance with the rapid development speed of electronic products, studies for forming fine and precise bumps have been actively made in the development of microelectronic packaging techniques and the like. In conventional bumps, methods of arranging bumps using solder have been generally used. Such solder bumps are characterized in that the pitch between the solder bumps decreases, thereby increasing a risk of short circuit between the solder bumps. Therefore, there is an issue related to the fine pitch, which can impose a limit to the miniaturization of a semiconductor package.

### SUMMARY

The present disclosure provides a semiconductor structure including a dielectric layer, a conductive pad embedded in the dielectric layer, and a bump disposed on the conductive pad, wherein the bump has a first top width and a bottom width, the first top width is greater than the bottom width, and a pair of spacers is disposed adjacent to the bump.

In some embodiments, the bump has an inverted trapezoid cross-section.

In some embodiments, the semiconductor structure further includes an under bump metal layer between the bump and the conductive pad.

In some embodiments, the under bump metal layer has a top surface, the bump has a sidewall, and the top surface and the sidewall form a sharp angle.

In some embodiments, one of the spacers has a triangle cross-section.

In some embodiments, the spacer has a first surface, the under bump metal layer has a second surface, and the first surface and the second surface are substantially coplanar.

In some embodiments, the conductive pad has a second top width, and the first top width of the bump is greater than the second top width of the conductive pad.

In some embodiments, the conductive pad has a second top width, and the second top width of the conductive pad is greater than the bottom width of the bump.

The present disclosure provides a method of manufacturing a semiconductor structure. The method includes the following steps. A dielectric layer embedded with a conductive pad is received. A photoresist layer with a first hole is formed on the dielectric layer, wherein the first hole substantially corresponds to the conductive pad. A pair of spacers is formed on a sidewall of the first hole to form a second hole between the pair of spacers. A bump is formed in the second hole. The photoresist layer is removed.

In some embodiments, before forming the photoresist layer with the first hole on the dielectric layer, the method further includes forming an under bump metal layer on the dielectric layer.

In some embodiments, after removing the photoresist layer, the method further includes removing a portion of the under bump metal layer to expose the dielectric layer.

In some embodiments, the first hole has a hole width, the conductive pad has a top width, and the hole width is greater than the top width.

In some embodiments, the second hole has a top hole width and a bottom hole width, and the top hole width is greater than the bottom hole width.

In some embodiments, one of the spacers has a triangle cross-section.

It is to be understood that both the foregoing general description and the following detailed description are by examples, and are intended to provide further explanation of the invention as claimed.

### BRIEF DESCRIPTION OF THE DRAWINGS

The disclosure can be more fully understood by reading the following detailed description of the embodiment, with reference made to the accompanying drawings as follows:

FIGS. 1-7 are cross-sectional views schematically illustrating intermediate stages in the manufacturing of a semiconductor structure, in accordance with some embodiments of the present disclosure.

FIG. 8 is a partial magnified view of FIG. 7.

### DETAILED DESCRIPTION

Reference will now be made in detail to the present embodiments of the, examples of which are illustrated in the accompanying drawings. Wherever possible, the same reference numbers are used in the drawings and the description to refer to the same or like parts.

The following embodiments are disclosed with accompanying diagrams for detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, for simplifying the drawings, some of the conventional structures and elements are shown with schematic illustrations.

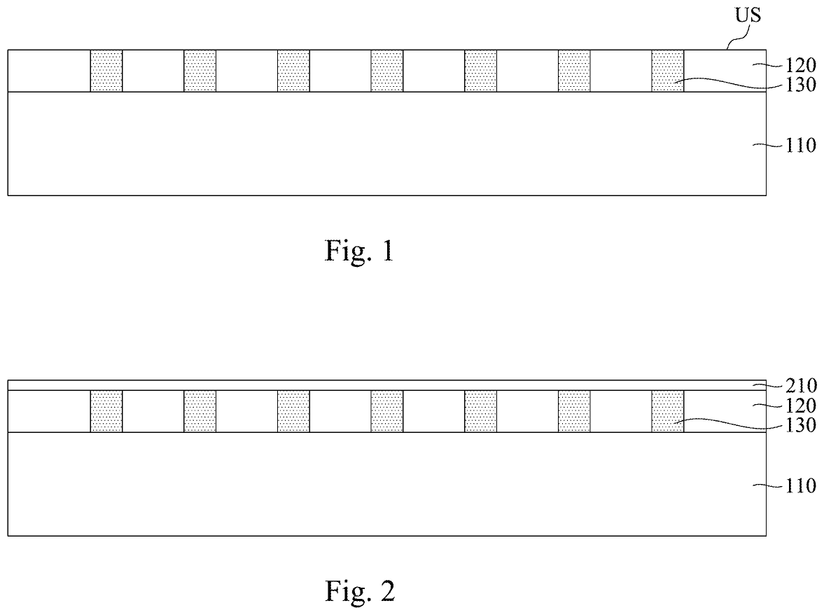

The present disclosure provides a method of manufacturing a semiconductor structure. FIGS. 1-7 are cross-sectional views schematically illustrating intermediate stages in the manufacturing of a semiconductor structure, in accordance with some embodiments of the present disclosure. It is understood that additional operations can be provided before, during, and after processes shown by FIGS. 1-7, and some of the operations described below can be replaced or eliminated, for additional embodiments of the method. The order of the operations/processes may be interchangeable.

As shown in FIG. 1, a substrate 110, a dielectric layer 120, and a conductive pad 130 are received. The dielectric layer 120 is disposed on the substrate 110. A conductive pad 130 is embedded in the dielectric layer 120 and exposed from an upper surface US of the dielectric layer 120. More specifically, the conductive pad 130 penetrates through the dielectric layer 120. In some embodiments, the dielectric layer 120 includes silicon dioxide (SiO₂).

As shown in FIG. 2, an under bump metal layer 210 is formed on the dielectric layer 120 and the conductive pad 130. For example, the material of the under bump metal layer 210 includes Ti, Cu, or a combination thereof.

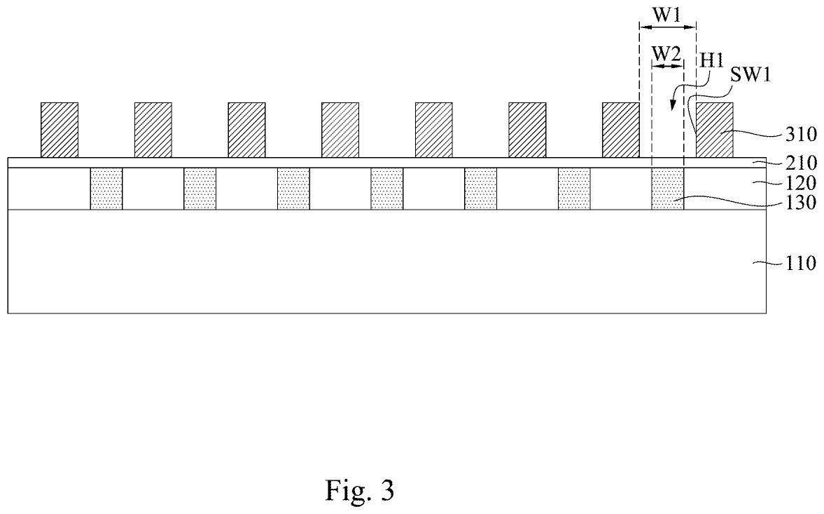

As shown in FIG. 3, a photoresist layer 310 with a first hole H1 is formed on the under bump metal layer 210, wherein the first hole H1 substantially corresponds to the conductive pad 130. In some embodiments, the first hole H1 has a hole width W1, the conductive pad 130 has a top width W2, and the hole width W1 is greater than the top width W2.

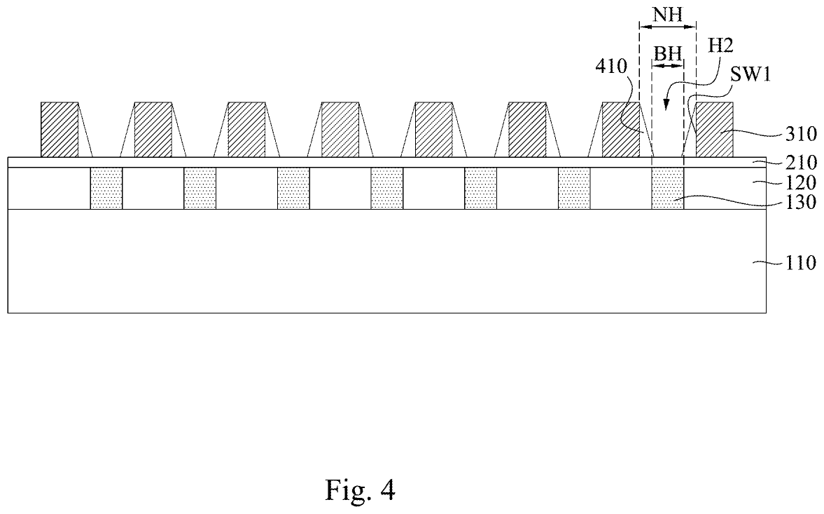

As shown in FIG. 4, a pair of spacers 410 is formed on a first sidewall SW1 of the first hole H1 to form a second hole H2 between the pair of spacers 410. More specifically, when forming the spacers 410 by, for example, etching, the under bump metal layer 210 can protect the dielectric layer 120 from being etching. In some embodiments, the under bump metal layer 210 is omitted. In some embodiments, the material of the spacers 410 is different from the material of the dielectric layer 120.

In some embodiments, the second hole H2 has a top hole width NH and a bottom hole width BH, and the top hole width NH is greater than the bottom hole width BH. In some embodiments, one of the spacers 410 has a triangle cross-section. In some embodiments, the spacer 410 includes silicon dioxide (SiO₂).

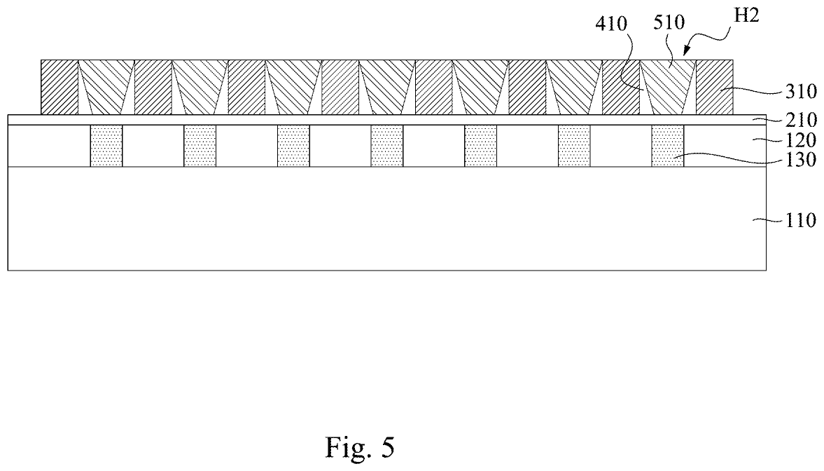

As shown in FIG. 5, a bump 510 is formed in the second hole H2. For example, the bump 510 is formed by the following steps. A conductive layer is formed on the spacers 410, the photoresist layer 310, and the under bump metal layer 210, and subsequently, a portion of the conductive layer is removed by, for example, chemical-mechanical planarization (CMP) process. In some embodiments, the bump 510 has an inverted trapezoid cross-section.

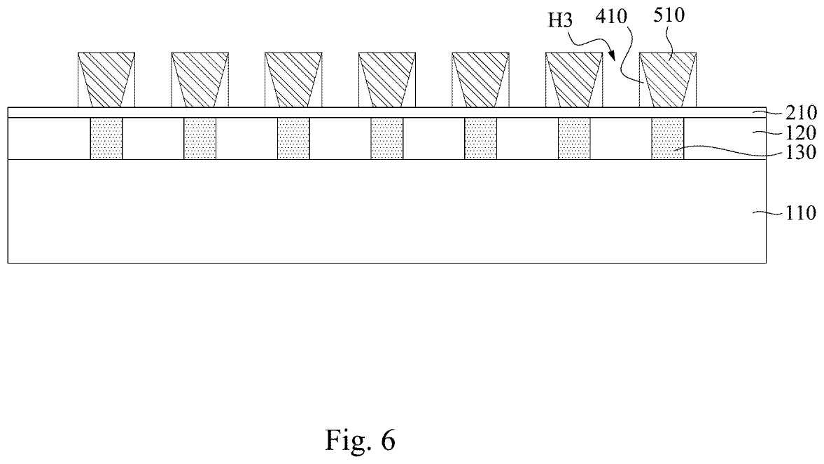

As shown in FIG. 6, the photoresist layer 310 is removed to expose the under bump metal layer 210. More specifically, the photoresist layer 310 is stripped to form a third hole H3 between adjacent spacers 410 to expose the under bump metal layer 210.

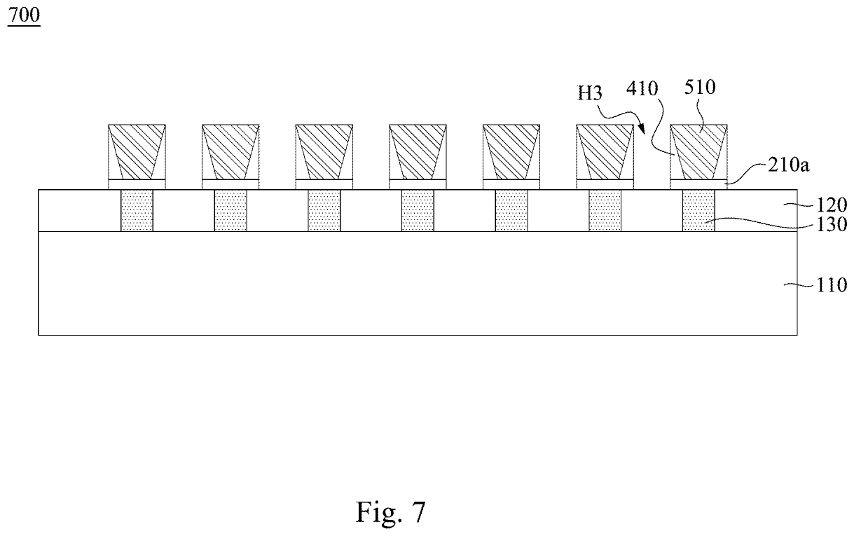

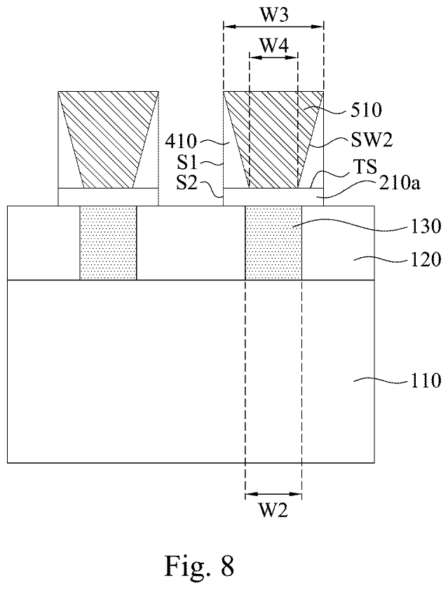

As shown in FIG. 7, a portion of the under bump metal layer 210 is removed to expose the dielectric layer 120 to form a semiconductor structure 700. FIG. 8 is a partial magnified view of FIG. 7.

Please refer to FIGS. 7 and 8 simultaneously. The semiconductor structure 700 includes the substrate 110, the dielectric layer 120, the conductive pad 130, the under bump metal layer 210a, the bump 510 and the pair of spacers 410. The dielectric layer 120 is disposed on the substrate 110. The conductive pad 130 is embedded in the dielectric layer 120. The bump 510 is disposed on the conductive pad 130. The bump 510 has a top width W3 and a bottom width W4. The top width W3 is greater than the bottom width W4. A pair of spacers 410 is disposed adjacent to the bump 510. Therefore, it can decrease a risk of short circuit between the adjacent bumps 510. In some embodiments, the top width W3 of the bump 510 is greater than the top width W2 of the conductive pad 130. Therefore, compared to conventional bump structure, the pitch between the adjacent bumps of the present disclosure is smaller.

Please still refer to FIGS. 7 and 8. The under bump metal layer 210a is disposed between the bump 510 and the conductive pad 130. In some embodiments, the under bump metal layer 210a has a top surface TS, the bump 510 has a second sidewall SW2, and the top surface TS and the second sidewall SW2 form a sharp angle. In some embodiments, the under bump metal layer 210a is omitted. The bump 510 is in direct contact with the conductive pad 130. The pair of spacers 410 is disposed adjacent to the bump 510. In some embodiments, one of the spacers 410 has a triangle cross-section. In some embodiments, the spacer 410 has a first surface S1, the under bump metal layer 210a has a second surface S2, and the first surface S1 and the second surface S2 are substantially coplanar.

In some embodiments, the top width W2 of the conductive pad 130 is greater than the bottom width W4 of the bump 510 as shown in FIG. 8. In some other embodiments, the top width W2 of the conductive pad 130 is equal to the bottom width W4 of the bump 510. In some other embodiments, the top width W2 of the conductive pad 130 is smaller to the bottom width W4 of the bump 510.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

1. A semiconductor structure, comprising:
a dielectric layer;
a conductive pad embedded in the dielectric layer; and
a bump disposed on the conductive pad, wherein the bump has a first top width and a bottom width, the first top width is greater than the bottom width, and a pair of spacers disposed adjacent to the bump.

2. The semiconductor structure of claim 1, wherein the bump has an inverted trapezoid cross-section.

3. The semiconductor structure of claim 1, further comprising an under bump metal layer between the bump and the conductive pad.

4. The semiconductor structure of claim 3, wherein the under bump metal layer has a top surface, the bump has a sidewall, and the top surface and the sidewall form a sharp angle.

5. The semiconductor structure of claim 1, wherein one of the spacers has a triangle cross-section.

6. The semiconductor structure of claim 1, wherein the spacer has a first surface, the under bump metal layer has a second surface, and the first surface and the second surface are substantially coplanar.

7. The semiconductor structure of claim 1, wherein the conductive pad has a second top width, and the first top width of the bump is greater than the second top width of the conductive pad.

8. The semiconductor structure of claim 1, wherein the conductive pad has a second top width, and the second top width of the conductive pad is greater than the bottom width of the bump.

9-14. (canceled)
